(19) United States
(12) Patent Application Publication
(10) Pub. No.: US 2025/0221279 A1
(43) Pub. Date: Jul. 3, 2025

(54) DISPLAY APPARATUS

(71) Applicant: LG Display Co., Ltd., Seoul (KR)

(72) Inventor: Hongmyeong JEON, Goyang-si (KR)

(21) Appl. No.: 18/950,970

(22) Filed: Nov. 18, 2024

(30) Foreign Application Priority Data
Dec. 28, 2023 (KR) 10-2023-0195496

(51) Int. Cl. H10K 59/80; H10K 59/122

(52) U.S. Cl. CPC H10K 59/879; H10K 59/122; H10K 59/873

(57) ABSTRACT

A display apparatus according to the present specification may include a substrate, a plurality of banks that partition a plurality of sub-pixels on the substrate, a light emitting element disposed on the plurality of sub-pixels, an encapsulation film disposed above the light emitting element, and a plurality of lenses disposed between the light emitting element and the encapsulation film.

### CROSS REFERENCE TO RELATED APPLICATION

The present application claims priority to Korean Patent Application No. 10-2023-0195496, filed Dec. 28, 2023, the entire contents of which is incorporated herein for all purposes by this reference.

### BACKGROUND

### Technical Field

The present specification relates to a display apparatus for displaying an image.

### Description of the Related Art

Display apparatus is applied to various electronic devices such as TVs, mobile phones, laptops, and tablets. To this end, research for developing display apparatus that are thinner, lighter, and have lower power consumption is being continuously conducted.

Among display apparatus for displaying various pieces of information as images, an organic light emitting diode (OLED) display apparatus includes a plurality of pixel areas arranged in an active area in which an image is displayed and a plurality of OLEDs corresponding to the plurality of pixel areas. Since the OLED is a self-luminous element for emitting light by itself, the OLED display apparatus has the advantage of a faster response time, higher luminous efficiency and luminance, a wider viewing angle, and superior contrast ratio and color gamut than liquid crystal display apparatus.

Recently, as demand for head mounted display (HMD) apparatus including the OLED display apparatus increases, research on the HMD devices is increasing. The HMD apparatus is an image display device for focusing on a distance close to a user's eyes using a device in the form of glasses or a helmet. The HMD apparatus can implement virtual reality (VR) or augmented reality (AR).

### BRIEF SUMMARY

The VR has an advantage of allowing a user to view a display of a 60-inch in size on a 1-inch display due to the user's excellent immersion. The OLED having a high resolution is applied to the HMD apparatus. The inventors of the present specification have recognized technical problems arising from the dense spacing of sub-pixels used to implement high-resolution displays.

Various embodiments of the present specification address one or more technical problems in the related art, including the above-identified technical problem by the inventors. For example, embodiments of the present specification are directed to providing a display apparatus in which the occurrence of color mixing can be prevented when light emitted from each sub-pixel is emitted in a direction of adjacent sub-pixels.

The embodiments of the present specification are also directed to simplifying a structure of a display apparatus by arranging microlenses between hydrophobic banks to improve an optical path. Therefore, the embodiments of the present specification are also directed to reducing the thickness of the entirety of a display apparatus.

In addition, the embodiments of the present specification are also directed to providing a display apparatus in which optical luminance can be increased by arranging microlenses having different shapes for each sub-pixel implementing different colors.

Technical benefits according to one embodiment of the present specification are not limited to the above-described benefits, and other benefits and advantages of the present disclosure that are not mentioned can be understood by the following description and will be more clearly understood by the embodiments of the present specification. In addition, it will be able to be easily seen that the benefits and advantages of the present specification can be achieved by devices and combinations thereof that are described in the claims.

A display apparatus according to one embodiment of the present specification may include a substrate, a plurality of banks that partition a plurality of sub-pixels on the substrate, a light emitting element disposed on the plurality of sub-pixels, an encapsulation film disposed the light emitting element, and a plurality of lenses disposed between the light emitting element and the encapsulation film.

### BRIEF DESCRIPTION OF THE SEVERAL VIEWS OF THE DRAWINGS

FIG. 1 is a schematic perspective view of a display apparatus according to an embodiment of the present specification.

FIG. 2 is a plan view schematically showing a portion of the display apparatus according to the embodiment of the present specification.

FIG. 3 is a cross-sectional view along line 3-3′ in FIG. 2.

FIGS. 4A, 4B, and 4C are views showing a light emission direction according to an angle of a lens.

FIG. 5 is a view for describing an angle of the lens of FIG. 3.

FIG. 6 is a cross-sectional view of a display apparatus according to another embodiment of the present specification.

FIG. 7 is a view showing an angle of the lens of FIG. 6.

FIG. 8 is a cross-sectional view of a display apparatus according to still another embodiment of the present specification.

FIG. 9 is a cross-sectional view of a display apparatus according to still another embodiment of the present specification.

FIGS. 10 to 14 are views for describing a method of manufacturing the display apparatus according to the embodiment of the present specification.

FIGS. 15 to 17 show a head mounted display apparatus including the display apparatus according to one embodiment of the present specification.

FIG. 18 is a side view of a head mounted apparatus that implements augmented reality according to an embodiment of the present specification.

### DETAILED DESCRIPTION

Advantages and features of the present specification and methods for achieving them will become clear with reference to embodiments described below in detail in conjunction with the accompanying drawings. However, the present specification is not limited to the embodiments disclosed below but will be implemented in various different forms, these embodiments are merely provided to make the disclosure of the present specification complete and fully inform those skilled in the art to which the present specification pertains of the scope of the present specification.

Since shapes, sizes, dimensions (e.g., length, width, height, thickness, radius, diameter, area, etc.), ratios, angles, numbers, and the like disclosed in the drawings for describing the embodiments of the present specification are illustrative, the present specification is not limited to the illustrated items.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference number indicates the same components throughout the specification. In addition, in describing the present specification, when it is determined that the detailed description of a related known technology may unnecessarily obscure the gist of the present specification, detailed description thereof will be omitted. When terms “comprises,” “has,” “consists of,” and the like described in the present specification are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description.

When a positional relationship is described, for example, when a positional relationship between two parts is described using the term “on,” “above,” “under,” “next to,” or the like, one or more other parts may be positioned between the two parts unless the term “immediately” or “directly” is used.

When a temporal relationship is described, for example, when a temporal relationship is described using the term “after,” “subsequently,” “then,” “before,” or the like, it may include a non-consecutive case unless the term “immediately” or “directly” is used.

Although terms such as first, second, and the like are used to describe various components, these components are not limited by these terms. The terms are only used to distinguish one component from another. Therefore, a first component described below may be a second component within the technical spirit of the present specification.

Features of various embodiments of the present specification can be coupled or combined partially or entirely, and various technological interworking and driving is possible, and the embodiments may be implemented independently of each other or implemented together in an associated relationship.

Hereinafter, a display apparatus according to each embodiment of the present disclosure will be described with reference to the accompanying drawings.

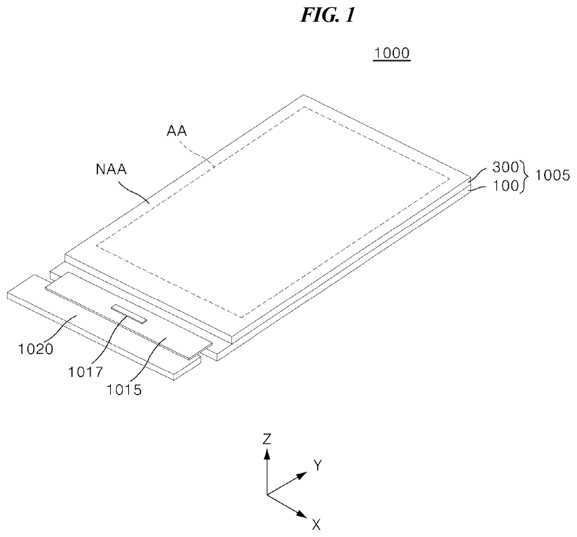

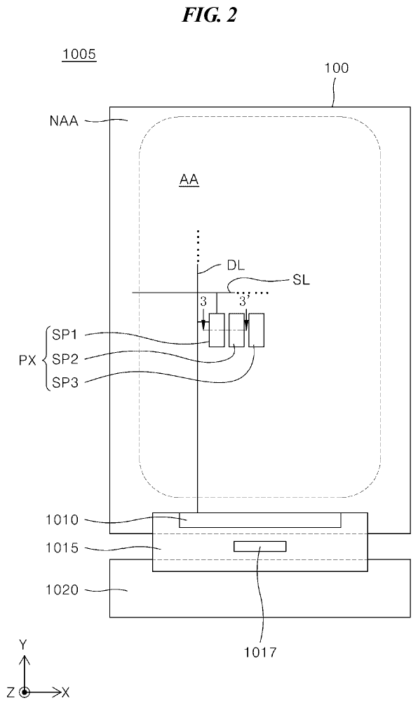

FIG. 1 is a schematic perspective view of a display apparatus according to an embodiment of the present specification. In addition, FIG. 2 is a plan view schematically showing a portion of the display apparatus according to the embodiment of the present specification.

Referring to FIGS. 1 and 2, a display apparatus 1000 according to an embodiment of the present specification may include a display panel 1005 having an active area AA and a non-active area NAA located outside the active area AA.

The display panel 1005 includes a first substrate 100 and a second substrate 300. The first substrate 100 may include a transparent plastic or glass. The second substrate 300 may include a transparent plastic film, a glass substrate, or an encapsulation film. The first substrate 100 or the second substrate 300 may have a quadrangular shape or have a quadrangular shape in which each corner has a rounded shape in a plan view. The second substrate 300 may also be referred to as a cover window, a window cover, or a cover glass that covers the first substrate 100.

A plurality of pixels PX may be disposed in the active area AA of the first substrate 100. A video or an image may be displayed in the active area (AA) through the plurality of pixels PX. Several drivers for driving the plurality of pixels PX disposed in the active area AA may be disposed in the non-active area NAA. For example, a driver may include a gate driver, a data driver, a touch driver, and a timing controller, but is not limited thereto.

A plurality of data lines DL and a plurality of scan lines SL may be disposed in the active area AA. Each of the plurality of data lines DL may be disposed to intersect each of the plurality of scan lines SL. One sub-pixel may be defined by one data line DL and one scan line SL that intersect each other, and a plurality of sub-pixels SP1, SPS, and SP3 may be disposed in the active area AA. For example, one sub-pixel may be electrically connected to the gate line and the data line.

The plurality of sub-pixels SP1, SP2, and SP3 may be disposed in a matrix form (M*N, in which M and N are natural numbers) on the active area AA of the first substrate 100. Each of the sub-pixels SP1, SP2, and SP3 may include a light emitting element and may emit light of red, green, or blue.

The non-active area NAA is an area surrounding the active area AA and may be defined as an area in which a video or image is not displayed. For example, the non-active area NAA may include an upper edge area, a lower edge area, a left edge area, and a right edge area of the display panel 1005. A flexible circuit board 1015 and a printed circuit board 1020 may be disposed on at least one edge of the non-active area NAA. An integrated circuit chip 1017 may be disposed on a flexible printed circuit board 1015. The flexible circuit board 1015 may have one side coupled to the first substrate 100 and the other side coupled to the printed circuit board 1020 to provide power and various signals for driving the light emitting element supplied from the printed circuit board 1020 to the active area AA of the first substrate 100. For example, various signals may include a high potential voltage, a low potential voltage, a scan signal, a data signal, a touch detection signal, etc.

The printed circuit board 1020 may supply signals to the integrated circuit chip 1017 disposed on the flexible printed circuit board 1015. Various components for supplying various signals to the integrated circuit chip 1017 may be disposed on the printed circuit board 1020. In FIG. 1, although one flexible circuit board 1015 and one printed circuit board 1020 are shown, the present specification is not limited thereto. For example, a plurality of flexible circuit boards 1015 and a plurality of printed circuit boards 1020 may be disposed at one edge of the first substrate 100.

A pad part 1010 may be located on the non-active area NAA of the first substrate 100 and may include a plurality of electrode pads. The flexible circuit board 1015 provided with the integrated circuit chip 1017 may be attached to the pad part 1010 disposed in the non-active area NAA of the display panel 1005. In one example, the flexible circuit board 1015 and the pad part 1010 may be attached by using an anisotropic conductive film. The electrode pads included in the pad part 1010 may include a plurality of power supply pads for transmitting power and various signals for driving the light emitting element supplied from the printed circuit board 1020 to the active area AA, a plurality of data supply pads, a control signal supply pad, or a plurality of common power supply pads, etc.

The display apparatus according to one embodiment of the present specification may be one of a top emission type or a bottom emission type according to a direction in which light emitted from the light emitting layer is emitted. Hereinafter, the top emission type will be described as an example.

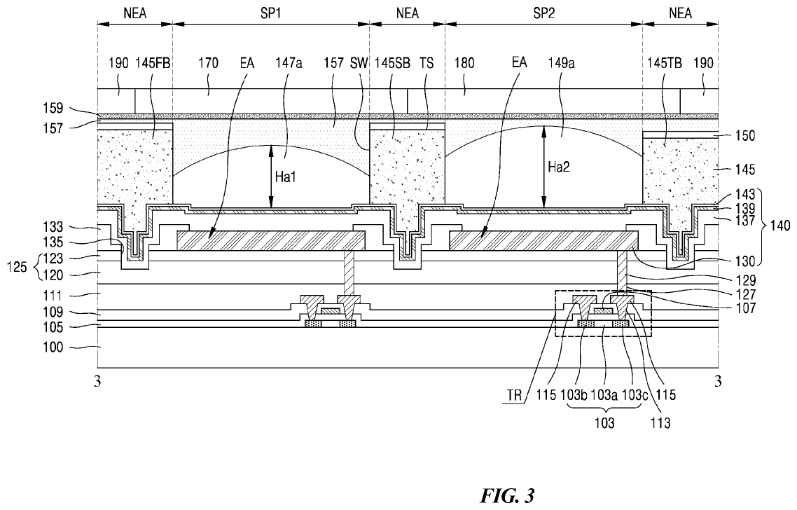

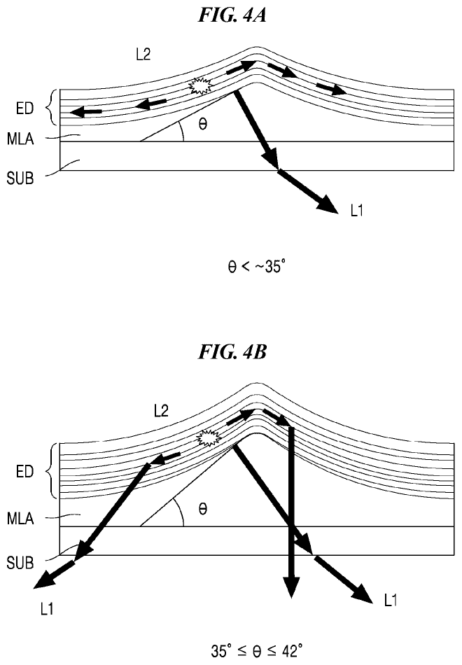

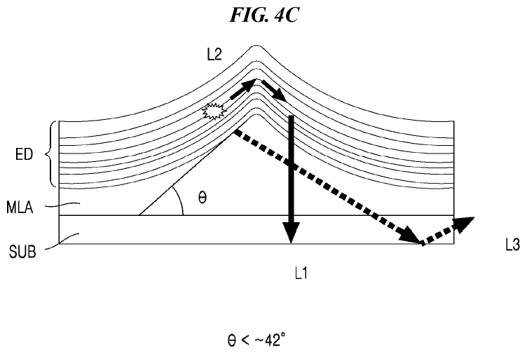

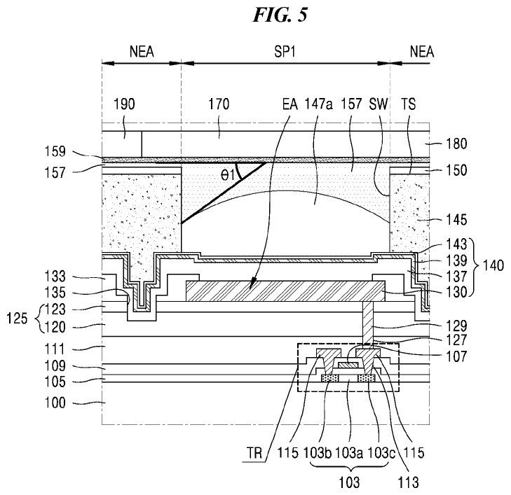

FIG. 3 is a cross-sectional view along line 3-3′ in FIG. 2. FIGS. 4A, 4B, and 4C are views showing a light emission direction according to an angle of a lens. FIG. 5 is a view for describing an angle of the lens of FIG. 3. In the embodiment of the present specification, only two sub-pixels SP1 and SP2 are described for convenience of description, but the present specification is not limited thereto.

Referring to FIGS. 3 to 5, a transistor TR may be disposed on the substrate 100. The substrate 100 may include a silicon wafer. In one embodiment, the substrate 100 may include glass or plastic.

On the substrate 100, a driving circuit including various signal lines, transistors, capacitors, etc., may be disposed for each sub-pixel SP1 and SP2. The signal lines may include a gate line, a data line, a power line, and a reference line, and the transistor TR may include a switching transistor and a driving transistor. For example, the switching transistor and the driving transistor may be formed on the substrate 100 using a complementary metal oxide semiconductor (CMOS) process.

The switching transistor is switched according to a gate signal supplied to the gate line to supply a data voltage supplied from the data line to the driving transistor and select the sub-pixels SP1 and SP2. The driving transistor serves to drive the light emitting element by supplying power to a first electrode of the sub-pixels SP1 and SP2 selected from the switching transistor.

The capacitor serves to maintain the data voltage supplied to the driving transistor for one frame, and electrodes of the capacitor may be electrically connected to the driving transistor.

The transistor TR may include a semiconductor layer 103, a gate insulating layer 105, a gate electrode 107, and source/drain electrodes 115. The gate insulating layer 105 may be disposed between the semiconductor layer 103 and the gate electrode 107. The transistor TR may further include an insulating layer that reduces or prevents permeation of moisture or impurities between the substrate 100 and the semiconductor layer 103.

The semiconductor layer 103 may be made of an oxide semiconductor or a silicon-based semiconductor material. For example, the semiconductor layer 103 may include a transparent oxide semiconductor material such as indium gallium-zinc-oxide (IGZO) or indium-zinc-oxide (IZO). In addition, the semiconductor layer 103 may include a polysilicon semiconductor material.

The semiconductor layer 103 may include a channel area 103a, a source area 103b, and a drain area 103c. The gate insulating layer 105 may be formed of a single layer or multiple layers of silicon oxide (SiOₓ) or silicon nitride (SiNₓ).

The gate electrode 107 may be disposed on the gate insulating layer 105. An area of the semiconductor layer 103 that vertically overlaps the gate electrode 107 may be a channel area 103a. The source area 103b and the drain area 103c may be located at either sides of the channel area 103a.

An interlayer insulating layer 109 and a passivation layer 111 may be sequentially disposed on the gate electrode 107.

The source/drain electrodes 115 filling a contact hole 113 passing through the interlayer insulating layer 109 and the gate insulating layer 105 may be disposed with the gate electrode 107 interposed therebetween. The source/drain electrodes 115 may be connected to the source area 103b and drain area 103c of the semiconductor layer 103, respectively.

A planarization layer 125 may be disposed on the passivation layer 111 and the source/drain electrodes 115. The planarization layer 125 may include a first planarization layer 120 and a second planarization layer 123. The planarization layer 125 serves to planarize a step caused by a lower circuit element including the driving transistor TR.

The planarization layer 125 may include a pixel contact hole 127 passing through the first planarization layer 120 and the second planarization layer 123 while exposing portions of surfaces of the source/drain electrodes 115 of the transistor TR. A pixel contact electrode 129 may fill the pixel contact hole 127 while one surface thereof is in contact with the source/drain electrodes 115.

The first electrode 130 may be disposed on the second planarization layer 123. The first electrode 130 may include a transparent metal oxide such as indium-tin-oxide (ITO) or indium-zinc-oxide (IZO). Alternatively, the first electrode 130 may include a single-layer or multilayered structure including a reflective metal film made of silver (Ag), aluminum (Al), gold (Au), nickel (Ni), chromium (Cr), and compounds thereof. The first electrode 130 may also be referred to as a pixel electrode or an anode electrode.

A trench 135 may be formed in boundary areas between the plurality of sub-pixels SP1 and SP2. For example, each trench 135 may include a boundary area between the first sub-pixel SP1 and the second sub-pixel SP2, a boundary area between the second sub-pixel SP2 and another neighboring sub-pixel, and a boundary area between the first sub-pixel SP1 and another neighboring sub-pixel.

The trench 135 may extend to a predetermined depth of the planarization layer 125. For example, the trench 135 may have a concave shape that passes through the second planarization layer 123 and extends to a predetermined area of the first planarization layer 120.

A fence 133 may be disposed at an edge of the first electrode 130. The fence 133 serves to prevent an end and side surfaces of the first electrode 130 from being exposed to the outside. For example, the fence 133 may be made of an insulating material. The exposed area of the first electrode 130 may be an emission area EA in which light is emitted to the outside.

An organic light emitting layer 137 may be disposed on the fence 133 and the first electrode 130. As the organic light emitting layer 137 is formed on the entire surface of the substrate 100, the organic light emitting layer 137 may have a shape extending along the shape of the trench 135. The organic light emitting layer 137 may include an organic material that emits white light. The organic light emitting layer 137 may include a stack structure including a hole transporting layer HTL, an emission layer EML, an electron transporting layer ETL, a hole blocking layer HBL, a hole injecting layer HIL, an electron blocking layer EBL, and an electron injecting layer EIL.

The second electrode 139 may be located on the organic light emitting layer 137. The second electrode 139 may be a common layer commonly formed in the plurality of sub-pixels SP1 and SP2. The second electrode 139 may also be referred to as a common electrode or a cathode electrode. The second electrode 139 may include a semi-transmissive material. For example, the second electrode 139 may include magnesium (Mg), silver (Ag), or an alloy of magnesium (Mg) and silver (Ag). A capping layer 143 may be further formed above the second electrode 139, but the present specification is not limited thereto. The capping layer 143 disposed on the second electrode 139 may include an insulating material. In one example, the capping layer 143 may include aluminum oxide (AlOₓ).

A light emitting element 140 including the first electrode 130, the organic light emitting layer 137, the second electrode 139, and the capping layer 143 may be formed. In addition, when the capping layer 143 is omitted, the light emitting element 140 including the first electrode 130, the organic light emitting layer 137, and the second electrode 139 may be formed.

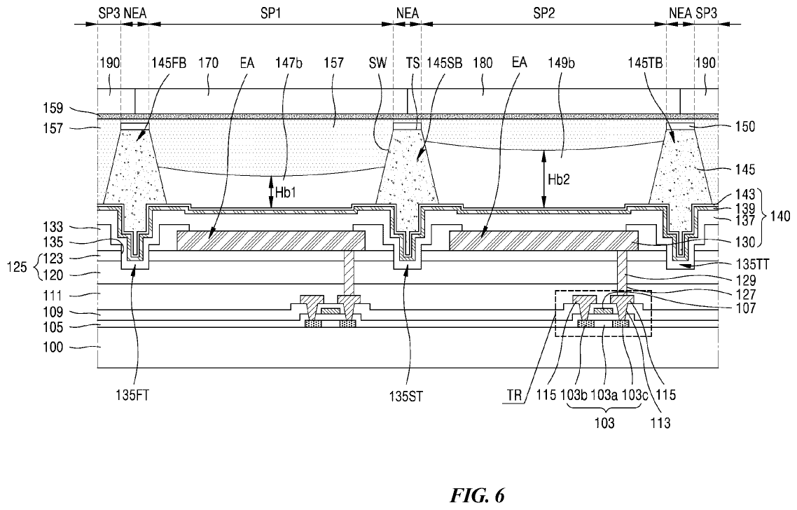

A bank 145 may be disposed in the boundary area between the plurality of sub-pixels SP1 and SP2. The bank 145 may have a pillar shape that fills the trench 135 and protrudes from a surface of the capping layer 143 to a predetermined height. The bank 145 may serve as a pixel defining layer that partitions the sub-pixels SP1 and SP2. In addition, it is possible to prevent light of different colors from being mixed and output to adjacent sub-pixels. The area where the bank 145 is disposed may be a non-emission area NEA in which light is not emitted to the outside. In one example, a side wall SW of the bank 145 may have a quadrangular pillar shape in which a top surface TS and the side wall SW are perpendicular, but is not limited thereto. Other shapes of the bank 145 will be described below with reference to FIG. 6.

The bank 145 may include a hydrophobic material that has a low affinity with respect to water molecules. For example, the bank 145 may include an organic insulating film such as polyimide or an epoxy. In one example, the bank 145 may include an opaque material to prevent light leakage to adjacent sub-pixels. For example, the bank 145 may include one of a black resin, graphite, and black ink.

A surface modification pattern 150 may be disposed on the top surface TS of the bank 145. The surface modification pattern 150 may have different properties from the bank 145. The surface modification pattern 150 may be a material having hydrophilic properties that have a high affinity with respect to water molecules unlike the bank 145 having hydrophobic properties. For example, the surface modification pattern 150 may be a hydrophilic organic material such as a photoresist material, polyethylene glycol (PEG), polyvinyl alcohol (PVA), or polyvinyl acetate (PVAc), but is not limited thereto.

Lenses 147a and 149a may be disposed in each of the sub-pixels SP1 and SP2. The lenses 147a and 149a may include the first lens 147a disposed on the first sub-pixel SP1 and the second lens 149a disposed on the second sub-pixel SP2. Bottom surfaces of the first lens 147a and the second lens 149a may each be disposed in contact with an uppermost surface of the light emitting element 140. For example, when the capping layer 143 is disposed on the uppermost surface of the light emitting element 140, the bottom surfaces of the lenses 147a and 149 may be in contact with the capping layer 143. In addition, when the second electrode 139 is disposed on the uppermost surface of the light emitting element 140, the bottom surfaces of the lenses 147a and 149 may be in contact with the second electrode 139.

The first lens 147a and the second lens 149a may have a first shape. For example, the first shape may be a hemispherical shape or a convex lens shape. Each of the first lens 147a and the second lens 149a that have the first shape may include a material having a first refractive index. In one example, the bank 145 may have a smaller height than 1.0 μm. When the bank 145 is formed to have a smaller height than 1.0 μm, the first lens 147a and the second lens 149a may be easily formed in a convex lens shape.

The first lens 147a and the second lens 149a may have different heights according to the characteristics of light emitted from each of the sub-pixels SP1 and SP2 that emit different colors. For example, the first lens 147a formed on the first sub-pixel SP1 may have a first height Hal from a bottom surface to a top surface of the lens. In addition, the second lens 149a formed on the second sub-pixel SP2 may have a top surface disposed above a top surface of the first lens 147a and have a second height Ha2 greater than the first height Ha1. In one example, the sub-pixels that emit the same color may have the same lens height.

Encapsulation films 157 and 159 may be disposed on the first lens 147a and the second lens 149a. The encapsulation films 157 and 159 may include the first encapsulation film 157 and the second encapsulation film 159. The first encapsulation film 157 serves to planarize a step caused by the bank 145, the first lens 147a, and the second lens 149a. The first encapsulation film 157 may include a material having hydrophilic properties. Here, as the surface modification pattern 150 having hydrophilic properties is located on the top surface of the bank 145 having hydrophobic properties, the bank 145 may be sealed by increasing an adhesive strength with the first encapsulation film 157.

The second encapsulation film 159 may be disposed on the first encapsulation film 157. The second encapsulation film 159 may be an inorganic insulating film. For example, the second encapsulation film 159 may include silicon nitride, aluminum nitride, zirconium nitride, titanium nitride, hafnium nitride, tantalum nitride, silicon oxide, aluminum oxide, or titanium oxide.

Color filters 170, 180, and 190 may be disposed on the second encapsulation film 159. The color filters 170, 180, and 190 may be provided to correspond one-to-one to the plurality of sub-pixels SP1, and SP2. The color filters 170, 180, and 190 may include the first color filter 170, the second color filter 180, and the third color filter 190. In the color filters 170, 180, and 190, the first color filter 170 of a first color may be located to correspond to the first sub-pixel SP1, and the second color filter 180 of a second color may be located to correspond to the second sub-pixel SP2. In addition, although not shown for convenience of description, the third color filter 190 of a third color may be located to correspond to the third sub-pixel that is another sub-pixel adjacent to each of the first sub-pixel SP1 and the second sub-pixel SP2. Here, the first color may be red, the second color may be green, and the third color may be blue, but the present specification is not limited thereto.

Meanwhile, the first lens 147a and the second lens 149a may have a hemispherical shape or a convex lens shape. The lens inclinations of the first lens 147a and the second lens 149a may have an angle θ1 (see FIG. 5) smaller than 42 degrees of the total reflection critical angle to prevent the occurrence of total reflection. For example, the inclinations of the first lens 147a and the second lens 149a may have angles that are greater than 35 degrees and smaller than 40 degrees.

Layers having different refractive indices are stacked above the light emitting element 140. In this case, among the light emitted from the light emitting element 140, light that is totally reflected and cannot be emitted to the outside according to a difference in refractive index between the stacked layers may be generated. As the amount of light that cannot be emitted to the outside due to total reflection increases, luminance may decrease, resulting in degrading the product quality of the display apparatus. Therefore, one of the methods for improving the total reflection of light is a micro lens array (MLA). The micro lens array MLA has a structure that improves light extraction efficiency by arranging multiple microlenses to change an optical path.

However, even when a plurality of microlenses is disposed, there is a problem in that light loss is caused by the total reflection. Hereinafter, description thereof will be made with reference to FIGS. 4A, 4B, and 4C. In FIGS. 4A, 4B, and 4C, for convenience of description, a bottom emission type in which light emits toward a substrate SUB is described as an example, but the present specification is not limited thereto. For example, the same manner may be applied to the top emission type.

Referring to FIGS. 4A, 4B, and 4C, the micro lens array MLA and the light emitting element ED are disposed in a direction from the bottom to the top on the substrate SUB. The micro lens array MLA may have a shape in which a concave lens continuously extends toward the substrate SUB. When the lens inclination of the micro lens array MLA has an angle θ smaller than 35 degrees with respect to the surface of the substrate SUB (see FIG. 4A), light L1 emits toward the substrate SUB, but as some light L2 among the light emitted from the light emitting element ED are laterally moved by the waveguide phenomenon, the loss of light emitted toward the substrate SUB that is the emission area EA may occur.

In addition, when the lens inclination of the micro lens array MLA has the angle θ greater than 42 degrees with respect to the surface of the substrate SUB (see FIG. 4C), some light L1 among the light emitted from the light emitting element ED may be emitted toward the substrate SUB due to the non-occurrence of the waveguide phenomenon. In addition, as the angle of the micro lens array MLA becomes greater than 42 degrees, light loss caused by the lateral movement of some light L2 among the light emitted from the light emitting element ED does not occur. However, some light L3 among the light emitted from the light emitting element ED may not be emitted to the outside by being totally reflected in the substrate SUB. Therefore, it can be understood that a critical angle at which the total reflection does not occur is an angle smaller than 42 degrees.

That is, when the lens inclination of the micro lens array MLA has an angle smaller than 35 degrees or greater than 42 degrees, the light efficiency emitted from the light emitting clement can be degraded.

In this regard, when the lens inclination of the micro lens array MLA has an angle greater than 35 degrees and smaller than 42 degrees (35°≤θ≤42°) (see FIG. 4B), the light L1 and L2 emitted from the light emitting element ED may be emitted toward the substrate SUB due to the non-occurrence of the waveguide phenomenon. As a result, the amount of light emitted from the light emitting element ED to the outside may increase, thereby increasing light efficiency.

Therefore, as shown in FIG. 5, the lens inclinations of the first lens 147a and the second lens 149a according to the embodiment of the present specification may have an angle θ1 smaller than 42 degrees. Specifically, the lens inclination angle θ1 at which the total reflection can be prevented in the first lens 147a and the second lens 149a may be in the range of 35 to 40 degrees. In addition, in one embodiment, the micro lens array MLA may have a convex lens shape instead of a concave lens shape continuously extending toward the substrate SUB, thereby improving the total reflection.

In the embodiment of the present specification, the occurrence of color mixing can be prevented by the bank 145 that is disposed at the boundary of neighboring sub-pixels SP1 and SP2 and has a protruding pillar shape. In addition, since the top surface of each of the first lens 147a and the second lens 149a is disposed at a location at least equal to or lower than the top surface TS of the bank 145, it is possible to prevent the light leakage phenomenon caused by allowing the light emitted from the first lens 147a and the second lens 149a to transmit to adjacent sub-pixels.

In addition, the first lens 147a and the second lens 149a may be disposed in contact with the top surface of the light emitting element 140. In addition, the first lens 147a and the second lens 149a may be covered with the first encapsulation film 157 and the second encapsulation film 159. Therefore, it is possible to reduce the overall thickness of the display apparatus.

Meanwhile, in one embodiment of the present specification, although a case where the first lens 147a and the second lens 149a have a convex lens shape has been described, the present specification is not limited thereto. The following description will be made with reference to the accompanying drawings.

Referring to FIG. 3, there are a plurality of banks 145 disposed on the substrate 100. The plurality of banks 145 includes a first bank 145FB, a second bank 145SB, and a third bank 145TB. Each bank of the plurality of banks 145 is spaced apart from each other. As shown in FIG. 3, the second bank 145SB is between the first bank 145FB and the third bank 145TB. The first lens 147a is disposed between the first bank 145FB and the second bank 145SB and the second lens 149a is disposed between the second bank 145SB and the third bank 145TB.

In some embodiments, the second electrode 139 at least continuously and contiguously extends from the first bank 145FB to the third bank 145TB. Here, the second electrode 139 extends below the first bank 145FB, the second bank 145SB, and the third bank 145TB. Accordingly, the second electrode 139 overlaps with the first bank 145FB, the second bank 145SB, and the third bank 145TB when seen from a plan view.

Similarly, the organic light emitting layer 137 continuously and contiguously extends from the first bank 145FB to the third bank 145TB. Here, the organic light emitting layer 137 extends below the first bank 145FB, the second bank 145SB, and the third bank 145TB. Accordingly, the organic light emitting layer 137 overlaps with the first bank 145FB, the second bank 145SB, and the third bank 145TB when seen from a plan view. In other words, the organic light emitting layer 137 overlaps with at least one of the banks of the plurality of banks 145 from a plan view.

In the illustration, the surface modification pattern 150 is on at least one of the banks of the plurality of banks 145 from a plan view. In some embodiments, the surface modification pattern 150 has different properties from the bank 145. For example, the surface modification pattern 150 has hydrophilic properties, and the bank 145 has hydrophobic properties.

In some embodiments, either the first lens 147a or the second lens 149a is spaced apart from the surface modification pattern 150 (see FIGS. 3, 5, 6, 7, 8, 9, and 15).

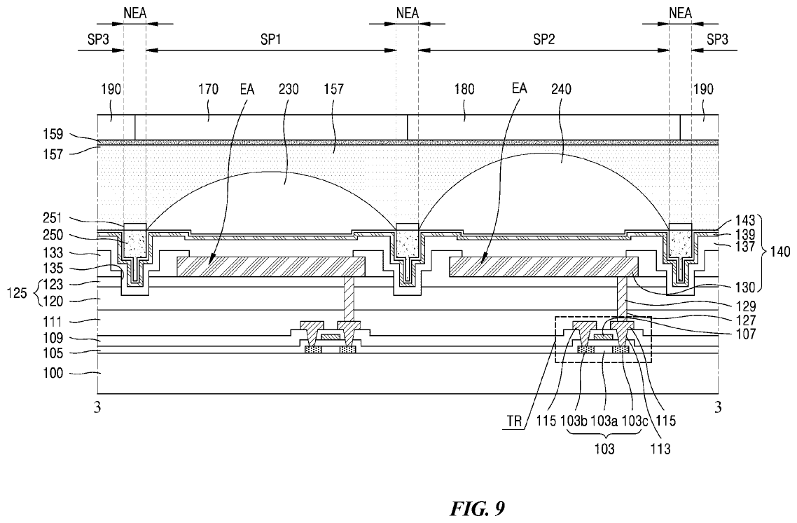

In some embodiments, either the first lens 147a or the second lens 149a directly contacts side surfaces of the surface modification pattern 150 (see FIG. 9).

In some embodiments, the first lens 147a directly contacts side surfaces of the first bank 145FB and the second bank 145SB, and the second lens 149a directly contacts side surfaces of the second bank 145SB and the third bank 145TB.

The lenses as shown in the drawings illustrate that the lenses can have various shapes. For example, some lenses can have a convex shape, and other lenses can have a concave shape. In addition, the lenses can have a variety of combination of shapes in the sub-pixels. In particular, the first lens (147a, 147b, 200, 230) has a first curvature and has a varying first thickness between the first bank 145FB and the second bank 145SB. Similarly, the second lens (149a, 149b, 210, 240) has a second curvature different from the first curvature and has a varying second thickness between the second bank 145SB and the third bank 145TB.

Due to the different shape of the lens (either concave or convex), the first lens can either have the greatest thickness at a location between the first bank 145FB and the second bank 145SB or the least thickness at a location between the first bank 145FB and the second bank 145SB.

Similarly, due to the different shape of the lens (either concave or convex), the second lens can either have the greatest thickness at a location between the second bank 145SB and the third bank 145TB or the least thickness at a location between the second bank 145SB and the third bank 145TB.

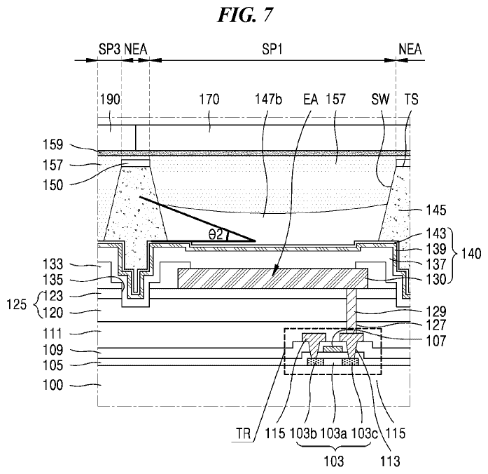

FIG. 6 is a cross-sectional view of a display apparatus according to another embodiment of the present specification. In addition, FIG. 7 is a view for describing an angle of the lens of FIG. 6. In particular, since FIG. 6 includes the same configuration as FIG. 3 except for the shape of the lens, overlapping descriptions will be omitted or briefly described, and different parts will be described. The same reference numerals may indicate the same components.

Referring to FIG. 6, the bank 145 may be disposed in the boundary area between the plurality of sub-pixels SP1 and SP2. The bank 145 may have a pillar shape that fills the trench 135 and protrudes from a surface of the capping layer 143 to a predetermined height. In one example, the bank 145 may have a regular taper shape of which its width becomes narrower toward the top surface TS. Therefore, the side wall SW of the bank 145 may have an inclined surface. When the bank 145 has a regular taper shape of which its width becomes narrower toward the top surface TS, the area of the light emission area EA may increase to the top surface TS of which width becomes narrower. In some embodiments, the trench 135 may protrude into the first planarization layer 120.

The first lens 147b and the second lens 149b that have a second shape different from the first shape may be disposed in the sub-pixels SP1 and SP2, respectively. The first lens 147b and the second lens 149b are covered with the first encapsulation film 157 and the second encapsulation film 159. The first lens 147b may be disposed on the first sub-pixel SP1, and the second lens 149b may be disposed on the second sub-pixel SP2. The first lens 147a and the second lens 149a may each be disposed in contact with the uppermost surface of the light emitting element 140.

The second shapes of the first lens 147b and the second lens 149b may be a concave lens shape. The first lens 147b and the second lens 149b may have different heights according to the characteristics of light emitted from each of the sub-pixels SP1 and SP2. For example, the first lens 147b formed on the first sub-pixel SP1 may have a first height Hb1 from a bottom surface to a top surface of the lens. In addition, the second lens 149b formed on the second sub-pixel SP2 may have a top surface disposed above the top surface of the first lens 147b and have a second height Hb2 greater than the first height Hb1. In one example, the bank 145 may have a greater height than 1.5 μm. When the bank 145 is formed to have a greater height than 1.5 μm, the first lens 147b and the second lens 149b may be easily formed in a concave lens shape.

The first encapsulation film 157 and the second encapsulation film 159 may include a material having a third refractive index (high refractive index). Here, the material having the high refractive index may be a material having a refractive index greater than the refractive index of air with respect to 1 of the refractive index of air. Each of the first lens 147b and the second lens 149b having the second shape may include a material having the first refractive index (low refractive index) different from the third refractive index (high refractive index) of the first encapsulation film 157. A material having a low refractive index may be a material having a smaller refractive index than a material having the high refractive index. The third refractive index may have a refractive index greater than the first refractive index.

The lens inclinations of the first lens 147b and the second lens 149b may have an angle θ2 smaller than 42 degrees of the total reflection critical angle to prevent the occurrence of the total reflection. When the lens inclination is greater than 42 degrees, total reflection may occur, thereby preventing light from being emitted to the outside. Therefore, referring to FIG. 7, the lens inclinations of the first lens 147b and the second lens 149b may have the angle θ2 smaller than 42 degrees. Specifically, the lens inclination angle θ2 at which the total reflection can be prevented in the first lens 147b and the second lens 149b may be in the range of 35 to 40 degrees.

Referring to FIG. 6, the plurality of trenches 135 is spaced apart from each other. The plurality of trenches 135 includes a first trench 135 FT, a second trench 135ST, and a third trench 135TT. Here, the first trench 135 FT overlaps with the first bank 145FB from a plan view, the second trench 135ST overlaps with the second bank 145SB from a plan view, and the third trench 135TT overlaps with the third bank 145TB from a plan view.

In some embodiments, the second electrode 139 (or the capping layer 143 on the second electrode 139, or the organic light emitting layer 137 disposed below the second electrode 139) continuously and contiguously extends down towards at least one of the trenches among the plurality of trenches 135 such that the second electrode 139 (or the capping layer 143 or the organic light emitting layer 137) overlaps the first electrode 130 from a horizontal view.

For example, the organic light emitting layer 137 extends into the trench 135 such that the organic light emitting layer 137 extends into a second planarization layer 123 that the first electrode 130 is disposed on. Similarly, the second electrode 139 (or the capping layer 143) extends into the trench 135 such that the second electrode 139 (or the capping layer 143) extends into the second planarization layer 123 that the first electrode 130 is disposed on.

In another embodiment of the present specification, the occurrence of the color mixing can be prevented by the bank 145 that is disposed at the boundary of neighboring sub-pixels SP1 and SP2 and has a protruding pillar shape. In addition, the area of the emission area EA may be increased by the bank 145 having a regular taper shape of which its width becomes narrower toward the top surface.

In addition, since the top surface of each of the first lens 147b and the second lens

149b is disposed at a location at least equal to or lower than the top surface TS of the bank 145, it is possible to prevent the light leakage phenomenon caused by allowing the light emitted from the first lens 147b and the second lens 149b to transmit to adjacent sub-pixels.

In addition, the first lens 147b and the second lens 149b may be disposed in contact with the top surface of the light emitting element 140. In addition, the first lens 147b and the second lens 149b may be covered with the first encapsulation film 157 and the second encapsulation film 159. Therefore, it is possible to reduce the overall thickness of the display apparatus.

Meanwhile, in the embodiment of the present specification, a case where lenses disposed to correspond to each of the plurality of sub-pixels have one of the shapes of a convex lens or a concave lens has been described, but the present specification is not limited thereto. The following description will be made with reference to the accompanying drawings.

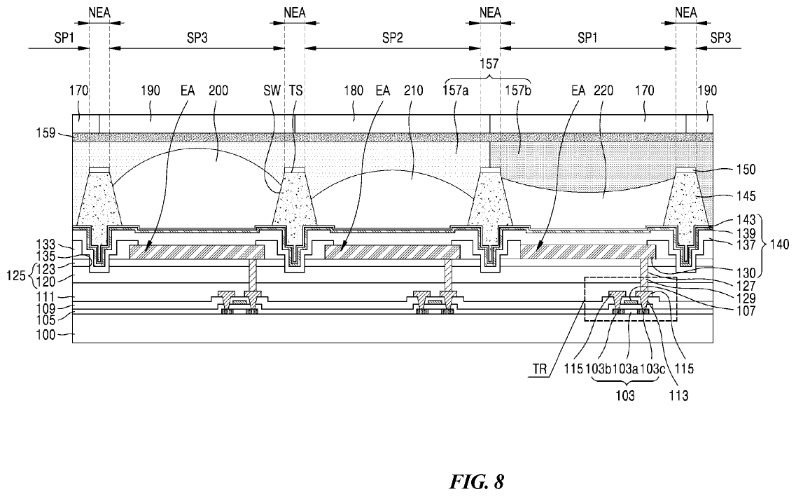

FIG. 8 is a cross-sectional view of a display apparatus according to still another embodiment of the present specification. In particular, since FIG. 8 includes the same configuration as FIG. 3 except for the shape of the lens, overlapping descriptions will be omitted or briefly described, and different parts will be described. The same reference numerals may indicate the same components. FIG. 8 shows the first sub-pixel SP1, the second sub-pixel SP2, and the third sub-pixel SP3. The first to third sub-pixels SP1, SP2, and SP3 may each emit light of different colors.

Referring to FIG. 8, the bank 145 may be placed in the boundary areas between the plurality of sub-pixels SP1, SP2, and SP3. The bank 145 may be provided in a pillar shape having a regular taper shape of which its width becomes narrower toward the top surface TS. Therefore, the side wall SW of the bank 145 may have an inclined surface. When the bank 145 has a regular taper shape of which its width becomes narrower toward the top surface TS, the area of the light emission area EA may increase to the top surface TS of which width becomes narrower. The surface modification pattern 150 may be disposed on the top surface TS of the bank 145. The surface modification pattern 150 may include a material having hydrophilic properties.

A first lens 200, a second lens 210, and a third lens 220 that have a first shape and a second shape different from the first shape may be disposed in the sub-pixels SP1, SP2, and SP3, respectively. The first lens 200 and the second lens 210 may have the first shape of a convex lens protruding toward the color filters 190, and 180. The third lens 220 may have the second shape of a concave lens that is recessed toward the substrate 100. The first lens 200, the second lens 210, and the third lens 220 may each be disposed in contact with the uppermost surface of the light emitting clement 140. The first lens 200 and the second lens 210 may include a material having a high refractive index, and the third lens 220 may include a material having a relatively lower refractive index than that of the first and second lenses 200 and 210. The lenses may all have the same shape, or may have different shapes in any combination. An example of higher refractive index is 1.68, and an example of lower refractive index is 1.4.

The first and second lenses 200 and 210 having a convex lens shape may be formed to have different heights in the third sub-pixel SP3 and the second sub-pixel SP2, respectively. For example, the first lens 200 formed on the third sub-pixel SP3 has a first height, and the second lens 210 formed on the second sub-pixel SP2 has a second height lower than the first height. The first lens and the second lens may have the same height.

The first lens 200, the second lens 210, and the third lens 220 are covered with the first encapsulation film 157 and the second encapsulation film 159. The first encapsulation film 157 may be in contact with the first to third lenses 200, 210, and 220. The first encapsulation film 157 may include a first part 157a and a second part 157b. The first part 157a of the first encapsulation film 157 may cover the third sub-pixel SP3 and the second sub-pixel SP2 in which the first and second lenses 200 and 210 are disposed, and the second part 157b may cover the first sub-pixel SP1 in which the third lens 220 is disposed. The first encapsulation film 157 may include a material having hydrophilic properties.

The first lens 200 and the second lens 210 contain the material having the high refractive index. Therefore, the first part 157a of the first encapsulation film 157 that covers the first and second lenses 200 and 210 to emit light in a front direction of the display apparatus may include the material having the low refractive index. In addition, the third lens 220 contains the material having the low refractive index. Therefore, the second part 157b of the first encapsulation film 157 covering the third lens 220 may include the material having the high refractive index.

The color filters 170, 180, and 190 may be disposed on the second encapsulation film 159. The color filters 170, 180, and 190 may include the first color filter 170, the second color filter 180, and the third color filter 190. In the color filters 170, 180, and 190, the first color filter 170 of the first color may be located to correspond to the first sub-pixel SP1, the second color filter 180 of the second color may be located to correspond to the second sub-pixel SP2, and the third color filter 190 of the third color may be located to correspond to the third sub-pixel SP3. In one example, the first color may be red, the second color may be green, and the third color may be blue, but the present specification is not limited thereto.

According to still another embodiment of the present specification, the first to third lenses 200, 210, and 220 disposed in the sub-pixels SP1, SP2, and SP3, respectively are formed to have different shapes to adjust the luminous efficiency of the light emitted from each sub-pixel.

Meanwhile, instead of having a pillar shape protruding from the surface of the light emitting element 140, the bank may be located to fill the trench 135 and have the top surface having the same height as the top surface of the light emitting element 140. The following description will be made with reference to the accompanying drawings.

FIG. 9 is a cross-sectional view of a display apparatus according to still another embodiment of the present specification. In particular, since FIG. 9 includes the same configuration as FIG. 3 except for the shape of the bank, overlapping descriptions will be omitted or briefly described, and different parts will be described. The same reference numerals may indicate the same components. In FIG. 9, for convenience of description, only the first sub-pixel SP1 and the second sub-pixel SP2 excluding the third sub-pixel SP3 are shown.

Referring to FIG. 9, a bank 250 may be disposed in the boundary area between the plurality of sub-pixels SP1 and SP2. The bank 250 may fill the trench 135 and have a surface at the same level as the top surface of the light emitting element 140. This makes the manufacturing process more simple. For example, when the uppermost surface of the light emitting element 140 is the capping layer 143, the bank 250 may have the same height as the capping layer 143, and when the second electrode 139 is disposed on the uppermost surface, the bank 250 may have the same height as the second electrode 139.

A first lens 230 and a second lens 240 that have a convex lens shape may be disposed in the sub-pixels SP1 and SP2, respectively. The first lens 230 and the second lens 240 are covered with the first encapsulation film 157 and the second encapsulation film 159. The first lens 230 may be disposed on the first sub-pixel SP1, and the second lens 240 may be disposed on the second sub-pixel SP2. The first lens 230 and the second lens 240 may each be disposed in contact with the uppermost surface of the light emitting element 140. The first lens 230 and the second lens 240 may have different thicknesses. For example, the second lens 240 may have a greater thickness than the first lens 230. The lens inclinations of the first lens 230 and the second lens 240 may be 35 to 40 degrees of an angle, which is smaller than the 42 degrees of the total reflection critical angle to prevent the occurrence of the total reflection.

As the bank 250 contains a hydrophobic material, the first lens 230 and the second lens 240 that contain a hydrophilic material do not flow onto the bank 250 and may be disposed to be spaced apart from the top surface of the bank 250.

A surface modification pattern 251 may be disposed on the top surface of the bank 250. The surface modification pattern 251 may include a hydrophilic material. Therefore, it is possible to increase the adhesive strength between the first encapsulation film 157 and the surface modification pattern 251, thereby preventing the peeling of the first encapsulation film 157.

The color filters 170, 180, and 190 corresponding one-to-one to the sub-pixels SP1, SP2, and SP3 may be disposed on the second encapsulation film 159. The color filters 170, 180, and 190 may include the first color filter 170, the second color filter 180, and the third color filter 190. In the color filters 170, 180, and 190, the first color filter 170 of a first color may be located to correspond to the first sub-pixel SP1, and the second color filter 180 of a second color may be located to correspond to the second sub-pixel SP2. In addition, although not shown for convenience of description, the third color filter 190 of a third color may be located to correspond to the third sub-pixel that is another sub-pixel adjacent to each of the first sub-pixel SP1 and the second sub-pixel SP2. Here, the first color may be red, the second color may be green, and the third color may be blue, but the present specification is not limited thereto.

According to still another embodiment of the present specification, it is possible to improve the convenience of the process (more simple to manufacture) by forming the bank 250 containing the hydrophobic material to fill the trench 135 and have a top surface having the same height as the top surface of the light emitting element 140.

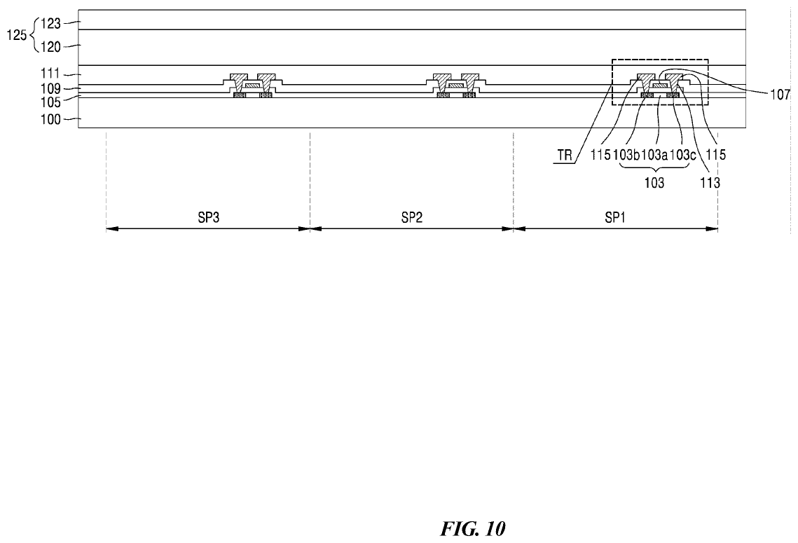

FIGS. 10 to 15 are views for describing a method of manufacturing the display apparatus according to the embodiment of the present specification. In particular, FIGS. 10 to 15 are cross-sectional views of the process for implementing the display apparatus of FIG. 8, and the same reference numerals as those of FIG. 8 may denote the same components.

Referring to FIG. 10, a plurality of transistors TR may be disposed on the substrate 100. The substrate 100 may include a silicon wafer. In one embodiment, the substrate 100 may include glass or plastic.

The transistor TR may include the semiconductor layer 103, the gate insulating layer 105, the gate electrode 107, and the source/drain electrodes 115. The gate insulating layer 105 may be disposed between the semiconductor layer 103 and the gate electrode 107. The semiconductor layer 103 may include the channel area 103a, the source area 103b, and the drain area 103c. The gate electrode 107 may be located on the gate insulating layer 105 and located to vertically overlap the channel area 103a.

The drain area 103c of the transistor TR may be in contact with the source/drain electrodes 115 that fill the contact hole 113 passing through the interlayer insulating layer 109, the first passivation layer 111, and the gate insulating layer 105.

The planarization layer 125 may be disposed on the first passivation layer 111 and the source/drain electrodes 115. The planarization layer 125 serves to planarize a step caused by a lower circuit element including the driving transistor TR. The planarization layer 125 may be a multi-layer. For example, the planarization layer 125 may have a structure in which the first planarization layer 120 and the second planarization layer 123 are stacked. The first planarization layer 120 or the second planarization layer 123 may contain one or more of organic insulating materials such as an acrylic resin, an epoxy resin, a phenolic resin, a polyamide resin, or a polyimide resin, but is not limited thereto.

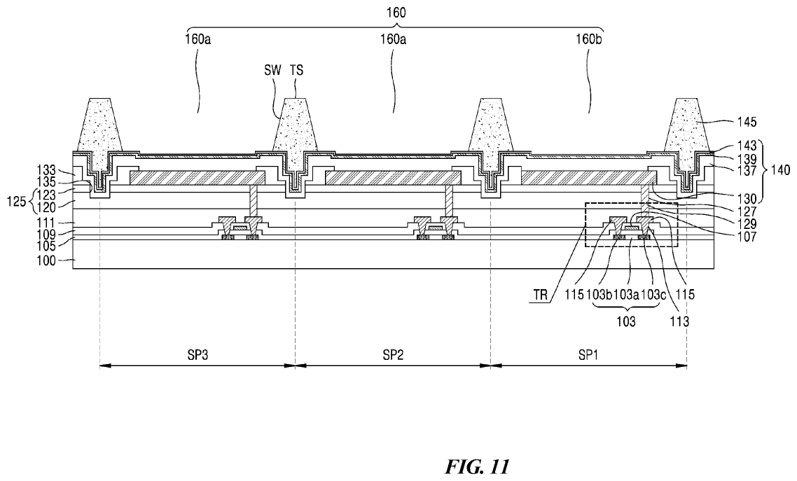

Referring to FIG. 11, the light emitting element 140 is formed on the lower structure in which the transistor TR is disposed.

More specifically, the first electrode 130 is formed in each of the sub-pixels SP1, SP2, and SP3 on the planarization layer 125. The first electrode 130 may be electrically connected to the source/drain electrodes 115 of the transistor TR through the contact electrode 129 that fills the contact hole 127. The exposed area of the first electrode 130 may be an emission area in which light is emitted to the outside.

The first electrode 130 may include a transparent metal oxide such as indium-tin-oxide (ITO) or indium-zinc-oxide (IZO). Alternatively, the first electrode 130 may include a single-layer or multilayered structure including a reflective metal film made of silver (Ag), aluminum (Al), gold (Au), nickel (Ni), chromium (Cr), and compounds thereof. The first electrode 130 may also be referred to as a pixel electrode or an anode electrode.

Next, the fence 133 covering the edge of the first electrode 130 is formed. The fence 133 serves to prevent the end (or the edge) of the first electrode 130 from being exposed to the outside. For example, the fence 133 may be made of an insulating material.

The trench 135 may be formed in the boundary areas between the plurality of sub-pixels SP1, SP2 and SP3. For example, each trench 135 may include a boundary area between the first sub-pixel SP1 and the second sub-pixel SP2, a boundary area between the second sub-pixel SP2 and the third sub-pixel SP3, and a boundary area between the third sub-pixel SP3 and the first sub-pixel SP1.

The trench 135 may extend to a predetermined depth of the planarization layer 125. For example, the trench 135 may pass through the second planarization layer 123 and extend to a predetermined area of the first planarization layer 120.

Next, the organic light emitting layer 137 may be formed on the first electrode 130. The organic light emitting layer 137 may be formed on the entire surface of the substrate 100 while covering the exposed surface of the first electrode 130. Therefore, the organic light emitting layer 137 may have a continuously curved shape (following the trench) along the shape of the trench 135. In one example, the organic light emitting layer 137 may contain the organic material that emits white light. The organic light emitting layer 137 may include the stack structure including the hole transporting layer HTL, the emission layer EML, the electron transporting layer ETL, the hole blocking layer HBL, the hole injecting layer HIL, the electron blocking layer EBL, and the electron injecting layer EIL.

The second electrode 139 may be formed on the organic light emitting layer 137. The second electrode 139 may be continuously formed on the entire surface of the substrate 100 along the shape of the organic light emitting layer 137. Therefore, the second electrode 139 may have a curved and uneven shape.

The second electrode 139 may include a semi-transmissive metal material. For example, the second electrode 139 may include magnesium (Mg), silver (Ag), or an alloy of magnesium (Mg) and silver (Ag).

The light emitting element 140 including the first electrode 130, the organic light emitting layer 137 and the second electrode 139 may be formed. When a voltage is applied to the first electrode 130 and the second electrode 139 by a selected signal, the light emitting element 140 may emit light through the emission area EA of each of the sub-pixels SP1, SP2, and SP3 through recombination of holes injected from the first electrode 130 and electrons injected from the second electrode 140.

The capping layer 143, which is a protective layer, may be formed on the second electrode 139. As the capping layer 143 is formed along the shape of the second electrode 139, the capping layer 143 may have a curved and uneven shape. The capping layer 143 may contain an insulating material. For example, the capping layer 143 may contain aluminum oxide (AlOₓ) formed by using an atomic layer deposition (ALD) method.

In addition, the bank 145 may be formed in the boundary areas between the plurality of sub-pixels SP1, SP2, and SP3. The bank 145 serves as a pixel defining layer that partitions each of the sub-pixels SP1, SP2, and SP3. The bank 145 may have a shape that fills the trench 135 and has a height protruding from the surface of the capping layer 143. Therefore, the bank 145 can prevent light of different colors from being output to adjacent sub-pixels by being mixed. In addition, the emission area can be defined through a bank hole 160 of the bank 145. The bank hole 160 may include a first bank hole 160a disposed in the second sub-pixel SP2 and the third sub-pixel SP3, and a second bank hole 160b disposed in the first sub-pixel SP3.

The bank 145 may contain a hydrophobic material having a low affinity with respect to water molecules. For example, the bank 145 may include an organic insulating film such as polyimide or an epoxy. In one example, the bank 145 may include one of a black resin, graphite, and black ink.

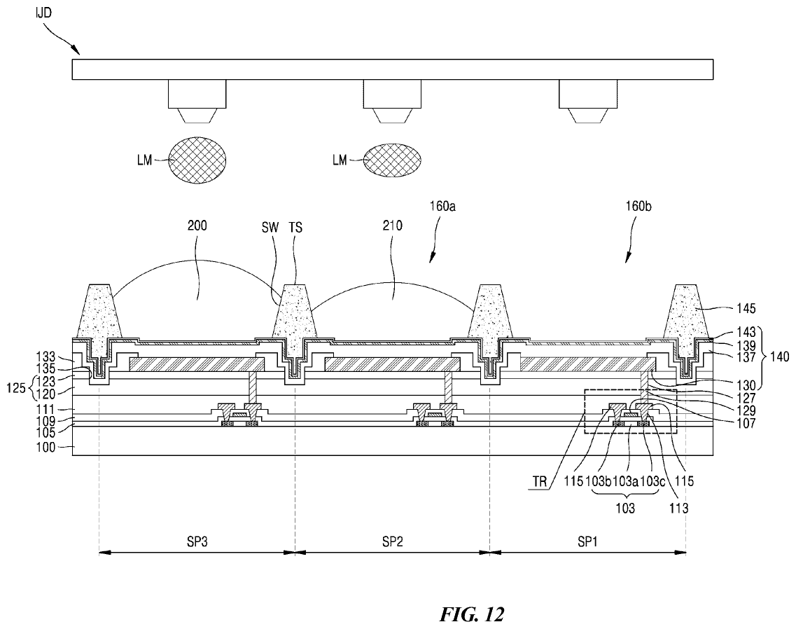

Referring to FIG. 12, the first lens 200 and the second lens 210 are formed in the first bank hole 160a of the bank 145. The first and second lenses 200 and 210 may have a first shape. Specifically, the first and second lenses 200 and 210 having the first shape are formed on the second electrode 143 of the light emitting element 140. The first and second lenses 200 and 210 having the first shape are each formed above the second electrode 143 of the light emitting clement 140 on the second sub-pixel SP2 and the third sub-pixel SP3 excluding the first sub-pixel SP1 among the sub-pixels SP1, SP2, and SP3.

The first and second lenses 200 and 210 having the first shape may be formed by using an ink-jet process. For example, an inkjet device IJD is disposed above the substrate 100, and a lens material LM is dropped from a head of the inkjet device IJD into the first bank hole 160a. The first and second lenses 200 and 210 having the first shape may be made of a hydrophilic material. As the bank 145 that partitions each of the sub-pixels SP1, SP2, and SP3 contains a hydrophobic material, the first and second lenses 200 and 210 having the first shape are formed in the bank hole 160. The first shapes of the first and second lenses 200 and 210 may be a hemispherical shape or a convex lens shape.

Since each of the first and second lenses 200 and 210 has a first refractive index and a convex lens shape, it is possible to increase the extraction amount of light emitted from the light emitting element 140 to the outside.

The first and second lenses 200 and 210 having the first shape may be formed to have different heights in the second sub-pixel SP2 and the third sub-pixel SP3, respectively. For example, the first lens 200 formed on the third sub-pixel SP3 has the first height, and the second lens 210 formed on the second sub-pixel SP2 has the second height lower than the first height.

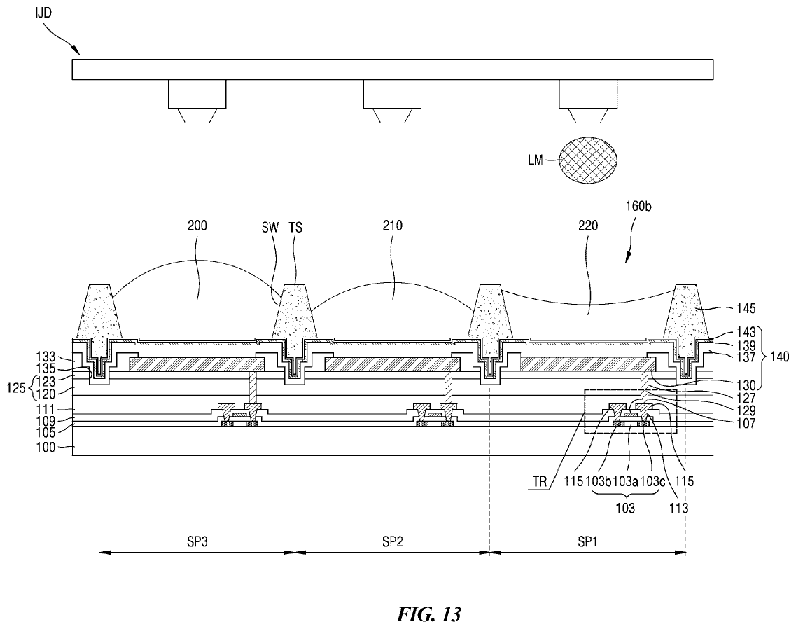

Referring to FIG. 13, the third lens 220 is formed in the second bank hole 160b of the first sub-pixel SP1. The third lens 220 may have the second shape which is different from the first shapes of the first and second lenses 200 and 210. Specifically, the third lens 220 having the second shape is formed on the second electrode 140 of the first sub-pixel SP1.

The third lens 220 having the second shape may be formed by using the inkjet process. For example, the inkjet device IJD is disposed above the substrate 100, and a lens material LM is dropped from the head of the inkjet device IJD into the second bank hole 160b. The third lens 220 having the second shape may be made of a hydrophilic material. Since the bank 145 that partitions the third sub-pixel SP3 includes the hydrophobic material, the third lens 220 having the second shape may be formed in the second bank hole 160b. The second shape of the third lens 220 may be a concave lens shape. The third lens 220 may have the second refractive index.

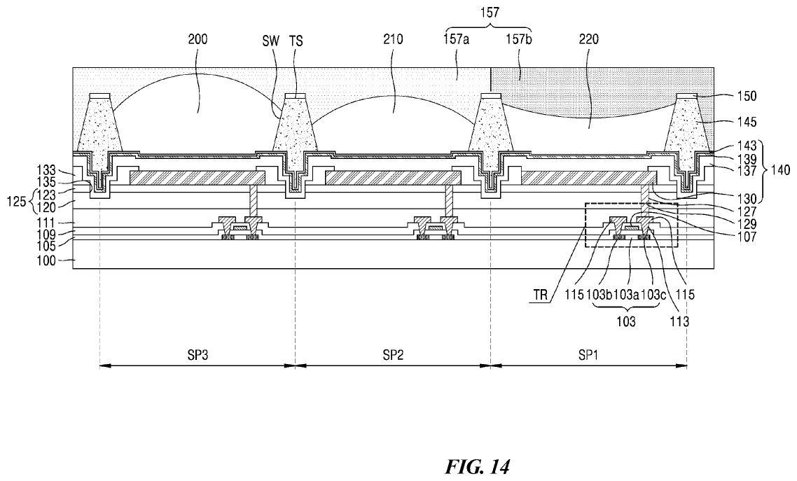

Referring to FIG. 14, the surface modification pattern 150 is formed on the top surface of the bank 145. The surface modification pattern 150 may have properties different from those of the bank 145 having hydrophobic properties. For example, the surface modification pattern 150 may be a material having hydrophilic properties, which has a high affinity with respect to water molecules. For example, the surface modification pattern 150 may be a hydrophilic organic material such as a photoresist material, polyethylene glycol (PEG), polyvinyl alcohol (PVA), or polyvinyl acetate (PVAc), but is not limited thereto. In addition, the surface modification pattern 150 may be formed on the top surface of the bank 145 through surface treatment with hydrophilic properties.

Next, the first encapsulation film 157 is formed on the substrate 100. The first encapsulation film 157 allows the lower structure having a step caused by the first to third lenses 200, 210, and 220 to have a flat surface.

The first encapsulation film 157 may include a first part 157a and a second part 157b. The first part 157a of the first encapsulation film 157 may cover the second sub-pixel SP2 and the third sub-pixel SP3 in which the first and second lenses 200 and 210 are disposed, and the second part 157b may cover the first sub-pixel SP1 in which the third lens 220 is disposed.

The first part 157a and the second part 157b of the first encapsulation film 157 may contain a material having hydrophilic properties. Here, as the surface modification pattern 150 having hydrophilic properties is located on the top surface of the bank 145 having hydrophobic properties, it is possible to increase the adhesive strength with the first encapsulation film 157.

In one example, the first part 157a and the second part 157b of the first encapsulation film 157 may have different refractive indices. For example, the first part 157a of the first encapsulation film 157 may have the third refractive index smaller than the first refractive indexes of the first and second lenses 200 and 210. The second part 157b of the first encapsulation film 157 may have a fourth refractive index greater than the second refractive index of the third lens 220.

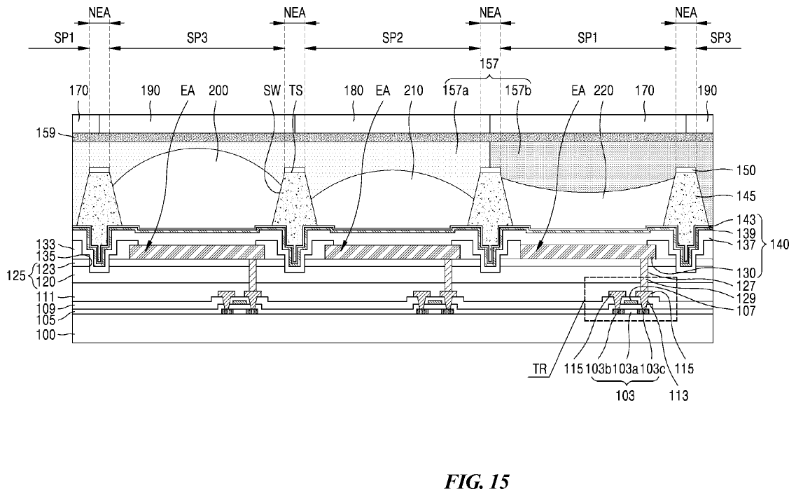

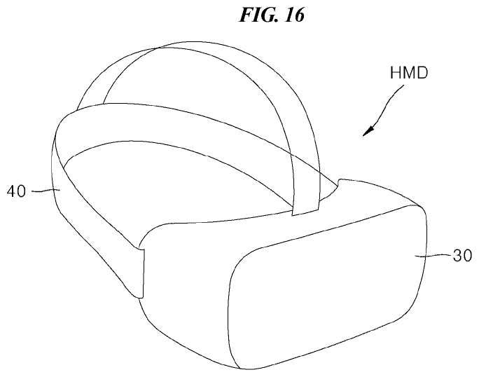

Referring to FIG. 15, the second encapsulation film 159 is formed on the first encapsulation film 157. The second encapsulation film 159 may be an inorganic insulating film. For example, the second encapsulation film 159 may include silicon nitride, aluminum nitride, zirconium nitride, titanium nitride, hafnium nitride, tantalum nitride, silicon oxide, aluminum oxide, or titanium oxide.

The color filters 170, 180, and 190 may be disposed on the second encapsulation film 159. The color filters 170, 180, and 190 may be provided to correspond one-to-one to the plurality of sub-pixels SP1, SP2, and SP3. The color filters 170, 180, and 190 may include the first color filter 170, the second color filter 180, and the third color filter 190. In the color filters 170, 180, and 190, the first color filter 170 using red pigment may be located to correspond to the first sub-pixel SP1, the second color filter 180 using green pigment may be located to correspond to the second sub-pixel SP2, and the third color filter 190 using blue pigment may be located to correspond to the third sub-pixel SP3.

In the embodiment of the present specification, the occurrence of the color mixing can be prevented by the bank 145 that partitions neighboring sub-pixels SP1, SP2, and SP3. In addition, the first to third lenses 200, 210, and 220 may be disposed in contact with the second electrode 139. In addition, since the first to third lenses 200, 210, and 220 are disposed between the first encapsulation film 157 and the second electrode 139, it is possible to simplify the structure, thereby reducing the overall thickness of the display apparatus.

In addition, it is possible to improve the optical path by arranging the banks including the hydrophobic material, thereby simplifying the structure of the display apparatus. Therefore, it is possible to reduce the thickness of the entirety of the display apparatus.

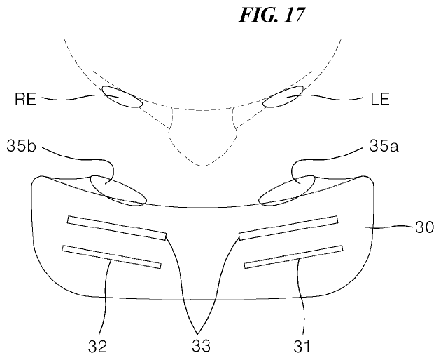

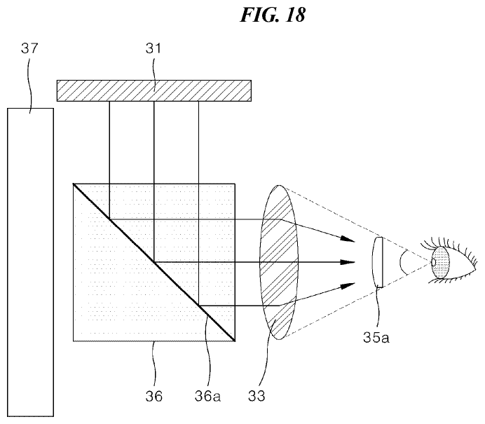

FIGS. 16 to 18 show a head mounted display apparatus including the display apparatus according to one embodiment of the present specification. Specifically, FIG. 16 is a schematic perspective view of a head mounted apparatus including the display apparatus according to the embodiment of the present specification, and FIG. 17 is a top view showing the head mounted apparatus implementing virtual reality. In addition, FIG. 18 is a side view of the head mounted apparatus that implements augmented reality.

Referring to FIG. 16, the head-mounted apparatus including the display apparatus according to the embodiment of the present specification may include a case part 30 and a head mounting band 40.

The case part 30 includes components, such as a display apparatus, a lens array, an eyepiece, a sound device, an accelerometer, and a position sensor, therein. The head mounting band 40 is fixed to the case part 30. An example in which the head mounting band 40 is formed to surround an upper surface and both side surfaces of the user's head, but the present disclosure is not limited thereto. The head mounting band 40 is used to secure the head mounted apparatus to a user's head. In another example, the head mounting band 40 may be an eyeglass frame (a frame of a pair of glasses) or a helmet-shaped structure that fully surrounds the user's head.

The head mounted apparatus may provide the user with each of an image implementing virtual reality (VR) or an image implementing augmented reality (AR) by including the display apparatus according to the embodiment of the present specification described in FIG. 3, FIG. 6, FIG. 8, or FIG. 9. Referring to FIG. 17, the head mounted display apparatus in which the VR is implemented may include a left-eye display device 31, a right-eye display device 32, a lens array 33, a left-eye eyepiece 35a, and a right-eye eyepiece 35b. The left-eye display device 31, the right-eye display device 32, the lens array 33, the left-eye eyepiece 35a, and the right-eye eyepiece 35b may be stored in the case part 30.

The left-eye display device 31 and the right-eye display device 32 may display the same image. When the same image is implemented on each of the left-eye display device 31 and the right-eye display device 32, the user may view the 2D image through the head mounted display device. Alternatively, the left-eye display device 31 may display an image for the left eye, and the right-eye display device 32 may display an image for the right eye different from the image for the left eye. In this case, the user may view a three-dimensional image through the head mounted display device. Each of the left-eye display device 31 and the right-eye display device 32 may include one of the above-described display device according to FIG. 3, FIG. 6, FIG. 8, or FIG. 9 and a modified example thereof.

The lens array 33 may be located to be spaced apart from each of the left-eye eyepiece 35a and the left-eye display device 31 and disposed between the left-eye eyepiece 35a and the left-eye display device 31. In other words, the lens array 33 may be located in front of the left-eye eyepiece 35a and behind the left-eye display device 31. In addition, the lens array 33 may be located to be spaced apart from each of the right-eye eyepiece 35b and the right-eye display device 32 and disposed between the right-eye eyepiece 35b and the right-eye display device 32. In other words, the lens array 33 may be located in front of the right-eye eyepiece 35b and behind the right-eye display device 32.

The lens array 33 may include a micro lens array, but is not limited thereto. In one example, the lens array 33 may include a pin hole array. Due to the lens array 33, enlarged images displayed on the left-eye display device 31 or the right-eye display device 32 may be visible to the user. The user's left eye LE may be located behind the left-eye eyepiece 35a, and the user's right eye RE may be located behind the right-eye eyepiece 35b.

Referring to FIG. 18, the head mounted display device in which the AR is implemented includes the left-eye display device 31, the lens array 33, the left-eye eyepiece 35a, a transmission reflector 36, and a transmission window 37. For convenience of description, only the configuration of the left eye is shown in FIG. 18, and the configuration of the right eye is also the same or similar to that of the left eye.

The left-eye display device 31, the lens array 33, the left-eye eyepiece 35a, the transmission reflector 36, and the transmission window 37 are stored in the case part 30 (see FIG. 16). The left-eye display device 31 may be disposed at one side, for example, an upper side of the transmission reflector 36 without covering the transmission window 37. Therefore, the left-eye display device 31 may provide images to the transparent reflector 36 without covering an external background visible through the transparent window 37.

The left-eye display device 31 may include one of the display device according to FIG. 3, FIG. 6, FIG. 8, or FIG. 9 and a modified example thereof. The lens array 33 may be provided between the left-eye eyepiece 35a and the transmission reflector 36. The user's left eye is located behind the left-eye eyepiece 35a.

The transmission reflector 36 is disposed between the lens array 33 and the transmission window 37. The transmission reflector 36 may include a reflective surface 36a for transmitting some of the light and reflecting others of the light. The reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The reflective surface 36a is formed so that the images displayed on the left-eye display device 31 proceed to the lens array 33.

Therefore, the user may view both the external background visible through the transparent window 37 and the images displayed by the left-eye display device 31. That is, since the user may view the real background and the virtual image as one image by allowing the real background and the virtual image to overlap each other, the AR can be implemented.

A display apparatus according to an embodiment of the present specification may include a substrate, a plurality of banks configured to partition a plurality of sub-pixels on the substrate, a light emitting element disposed on the plurality of sub-pixels, an encapsulation film disposed above the light emitting element, and a plurality of lenses disposed between the light emitting element and the encapsulation film.

In the display apparatus according to some embodiments of the present specification, the lens may have different heights for each sub-pixel that emits light different colors among the plurality of sub-pixels.

In the display apparatus according to some embodiments of the present specification, a bottom surface of the lens may be in contact with a top surface of the light emitting element.

In the display apparatus according to some embodiments of the present specification, the light emitting element may include a first electrode disposed between the banks, an organic light emitting layer disposed on the first electrode; and a second electrode disposed on the organic light emitting layer, in which the organic light emitting layer may emit white light.

In the display apparatus according to some embodiments of the present specification, the bank may further include a surface modification pattern including a hydrophilic material on a top surface thereof, in which the bank may include a hydrophobic material, and the surface modification pattern may have one surface in contact with the top surface of the bank and the other surface facing the one surface and in contact with the encapsulation film.

In the display apparatus according to some embodiments of the present specification, the bank may contain an opaque material.

In the display apparatus according to some embodiments of the present specification, at least one of the plurality of lenses may have a first shape or one or more of the first shape and a second shape different from the first shape.

In the display apparatus according to some embodiments of the present specification, the first shape may include a hemispherical shape or a convex lens shape, and the second shape may include a concave lens shape.

In the display apparatus according to some embodiments of the present specification, the lens may include a first shape of a hemispherical shape or a convex lens shape, and the lens may have an inclination at an angle greater than 35 degrees and smaller than 40 degrees with respect to a flat surface of the encapsulation film.

In the display apparatus according to some embodiments of the present specification, the lens may include a high refractive index material including a first shape of a hemispherical shape or a convex lens shape, and the encapsulation film may include a low refractive index material having a relatively smaller refractive index than the lens.

In the display apparatus according to some embodiments of the present specification, the lens may include a second shape of a concave lens shape, and the lens may have an inclination at an angle greater than 35 degrees and smaller than 40 degrees with respect to the flat surface of an uppermost surface of the light emitting element.

In the display apparatus according to some embodiments of the present specification, the lens may include a low refractive index material including a second shape of a concave lens shape, and the encapsulation film covering the lens may include a high refractive index material having a relatively higher refractive index than the lens.

In the display apparatus according to some embodiments of the present specification, the top surface of the lens may be located at a location that is at least equal to or lower than the top surface of the bank.

In the display apparatus according to some embodiments of the present specification, the lens may include a second shape of a concave lens shape, and the bank may have a regular taper shape of which width becomes narrower toward the top surface.

The display apparatus according to some embodiments of the present specification may further include a trench disposed in a boundary area between a plurality of sub-pixels, and the bank may have a height that fills the trench and have the top surface having the same height as the top surface of the light emitting element.

According to the embodiments of the present specification, it is possible to increase the extraction efficiency of the light emitted externally from the light emitting element by arranging lenses having different thicknesses or shapes in each of the plurality of sub-pixels. As light extraction efficiency increases, the light emitting element can be driven with low power, thereby reducing production energy.

In addition, according to the embodiments of the present specification, it is possible to improve the optical path by arranging the banks including the hydrophobic material between the lenses, thereby simplifying the structure of the display apparatus. Therefore, it is possible to reduce the thickness of the entirety of the display apparatus.

In addition, according to the embodiments of the present specification, by arranging the bank including the hydrophobic material between the sub-pixels, it is possible to prevent the occurrence of the color mixing due to the emission of light emitted from each sub-pixel toward an adjacent sub-pixel.

The effects of the present specification are not limited to the above-described effects, and other effects that are not mentioned will be able to be clearly understood by those skilled in the art from the following description.

Although the embodiments of the present specification have been described in more detail with reference to the accompanying drawings, the present specification is not necessarily limited to these embodiments, and various modifications may be carried out without departing from the technical spirit of the present specification. Therefore, the embodiments disclosed in the present specification are not intended to limit the technical spirit of the present specification, but is intended to describe the same, and the scope of the technical spirit of the present specification is not limited by these embodiments. Therefore, it should be understood that the above-described embodiments are illustrative and not restrictive in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate;
a plurality of banks that partition a plurality of sub-pixels on the substrate, each bank of the plurality of banks spaced apart from each other;
a light emitting element disposed on the substrate;
an encapsulation film disposed on the light emitting element; and
a plurality of lens disposed between the light emitting element and the encapsulation film.

2. The display apparatus of claim 1, wherein a lens of plurality of lens has a different height for each sub-pixel that emits light of different colors among the plurality of sub-pixels.

3. The display apparatus of claim 1, wherein a bottom surface of the lens is in contact with a top surface of the light emitting element.

4. The display apparatus of claim 1, wherein a top surface of the lens is in contact with the encapsulation film.

5. The display apparatus of claim 1, wherein the light emitting element includes;
a first electrode disposed between the banks;
an organic light emitting layer disposed on the first electrode; and
a second electrode disposed on the organic light emitting layer.

6. The display apparatus of claim 5, further comprising a capping layer disposed on the second electrode.

7. The display apparatus of claim 1, wherein the bank further includes a surface modification pattern including a hydrophilic material on a top surface thereof, and
wherein the bank includes a hydrophobic material, and the surface modification pattern has one surface in contact with a top surface of the bank and the other surface facing the one surface and in contact with the encapsulation film.

8. The display apparatus of claim 1, wherein at least one of the plurality of lenses has a first shape or one or more of the first shape and a second shape different from the first shape.

9. The display apparatus of claim 8, wherein the first shape includes a hemispherical shape or a convex lens shape, and the second shape includes a concave lens shape.

10. The display apparatus of claim 1, wherein the lens includes a first shape of a hemispherical shape or a convex lens shape, and
wherein the lens has an inclination at an angle greater than 35 degrees and smaller than 40 degrees with respect to a flat surface of the encapsulation film.

11. The display apparatus of claim 1, wherein the lens includes a high refractive index material including a first shape of a hemispherical shape or a convex lens shape, and
wherein the encapsulation film includes a low refractive index material having a relative smaller refractive index than that of the lens.

12. The display apparatus of claim 1, wherein the lens includes a second shape of a concave lens shape, and
wherein the lens has an inclination at an angle greater than 35 degrees and smaller than 40 degrees with respect to a flat surface of an uppermost surface of the light emitting element.

13. The display apparatus of claim 1, wherein the lens includes a low refractive index material including a second shape of a concave lens shape, and the encapsulation film covering the lens includes a high refractive index material having a relatively greater refractive index that that of the lens.

14. The display apparatus of claim 1, wherein the lens has a top surface located at a location at least equal to or lower than the top surface of the bank.

15. The display apparatus of claim 1, wherein the lens includes a second shape of a concave lens shape, and
wherein the bank has a regular taper shape of which width becomes narrower toward a top surface thereof.

16. The display apparatus of claim 1, further comprising a trench disposed in a boundary area between the plurality of sub-pixels,
wherein the bank has a height that fills the trench and has a top surface having the same height as the top surface of the light emitting element.

17. A display apparatus comprising:
a substrate;
a plurality of banks on the substrate, the plurality of banks including a first bank, a second bank, and a third bank, each bank being spaced apart from each other, the second bank being between the first bank and the third bank;
a light emitting element including a first electrode, a second electrode, and a light emitting layer between the first and second electrodes;
a first lens disposed between the first bank and the second bank;
a second lens disposed between the second bank and the third bank; and
an encapsulation film on the first lens, the second lens, and the light emitting element.

18. The display apparatus of claim 17, wherein the second electrode continuously and contiguously extends from the first bank to the third bank.

19. The display apparatus of claim 17, wherein the light emitting layer continuously and contiguously extends from the first bank to the third bank.

20. The display apparatus of claim 17, wherein the light emitting layer overlaps with at least one of the banks of the plurality of banks from a plan view.

21. The display apparatus of claim 17, further comprising: a surface modification pattern on at least one of the banks of the plurality of banks from a plan view,
wherein the surface modification pattern has different properties from the bank.

22. The display apparatus of claim 21, wherein the surface modification pattern has hydrophilic properties, and
wherein the bank has hydrophobic properties.

23. The display apparatus of claim 21, wherein either the first lens or the second lens is spaced apart from the surface modification pattern.

24. The display apparatus of claim 21, wherein either the first lens or the second lens directly contacts side surfaces of the surface modification pattern.

25. The display apparatus of claim 17, wherein the first lens directly contacts side surfaces of the first bank and the second bank, and
wherein the second lens directly contacts side surfaces of the second bank and the third bank.

26. The display apparatus of claim 17, wherein the first lens has a first curvature and has a varying first thickness between the first bank and the second bank, and
wherein the second lens has a second curvature different from the first curvature and has a varying second thickness between the second bank and the third bank.

27. The display apparatus of claim 17, wherein the first lens has a first curvature and is thickest at a location between the first bank and the second bank, and
wherein the second lens has a second curvature and is thinnest at a location between the second bank and the third bank.

28. The display apparatus of claim 17, further comprising a plurality of trenches spaced apart from each other, the plurality of trenches including a first trench, a second trench, and a third trench,
wherein the first trench overlaps with the first bank from a plan view,
wherein the second trench overlaps with the second bank from a plan view, and
wherein the third trench overlaps with the third bank from a plan view.

29. The display apparatus of claim 28, wherein the second electrode continuously and contiguously extends down towards at least one of the trenches among the plurality of trenches such that the second electrode overlaps the first electrode from a horizontal view.
